(19) United States
(12) Patent Application Publication
(10) Pub. No.: US 2014/0140024 A1
(43) Pub. Date: May 22, 2014

(54) CIRCUIT BOARD MOUNTING APPARATUS

(71) Applicant: HON HAI PRECISION INDUSTRY CO., LTD., New Taipei (TW)

(72) Inventors: CHIEN-CHUNG HUANG, New Taipei (TW); ZHENG-HENG SUN, New Taipei (TW)

(73) Assignee: HON HAI PRECISION INDUSTRY CO., LTD., New Taipei (TW)

(21) Appl. No.: 13/726,656

(22) Filed: Dec. 26, 2012

(30) Foreign Application Priority Data
Nov. 21, 2012 (CN) 2012104746750

(51) Int. Cl. H05K 5/02

(52) U.S. Cl. CPC H05K 5/0217
USPC 361/759

(57) ABSTRACT

A circuit board mounting apparatus includes a circuit board, a chassis, a first mounting member, a second mounting member, and a fastener. The chassis includes a side plate defining a through hole, a first hole, and a second hole communicating with the first hole. Each of the first and second mounting members includes two latching legs detachably mounted to a front end of the circuit board. A neck protrudes from a front end of the first mounting member, and a head is formed on a front end of the neck. The neck extends through the first hole and engages in the second hole. The head abuts a front side of the side plate. A fixing hole is defined in a front end of the second mounting member. The fastener extends through the through hole and engages in the fixing hole, to mount the circuit board to the side plate.

### BACKGROUND

1. Technical Field

The present disclosure relates to a circuit board mounting apparatus.

2. Description of Related Art

In electronic devices, circuit boards may be mounted inside the devices with a number of screws extended through the circuit board and engaged in a number of posts on a bottom plate of the chassis of the devices. However, fastening screws manually in the chassis can be difficult and inconvenient because of limited space for maneuvering.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of a first embodiment of a circuit board mounting apparatus.

FIG. 2 is an assembled, isometric view of FIG. 1.

FIG. 3 is similar to FIG. 2, but viewed from another perspective.

FIG. 4 is a partial, exploded, isometric view of a second embodiment of a circuit board mounting apparatus.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean “at least one”.

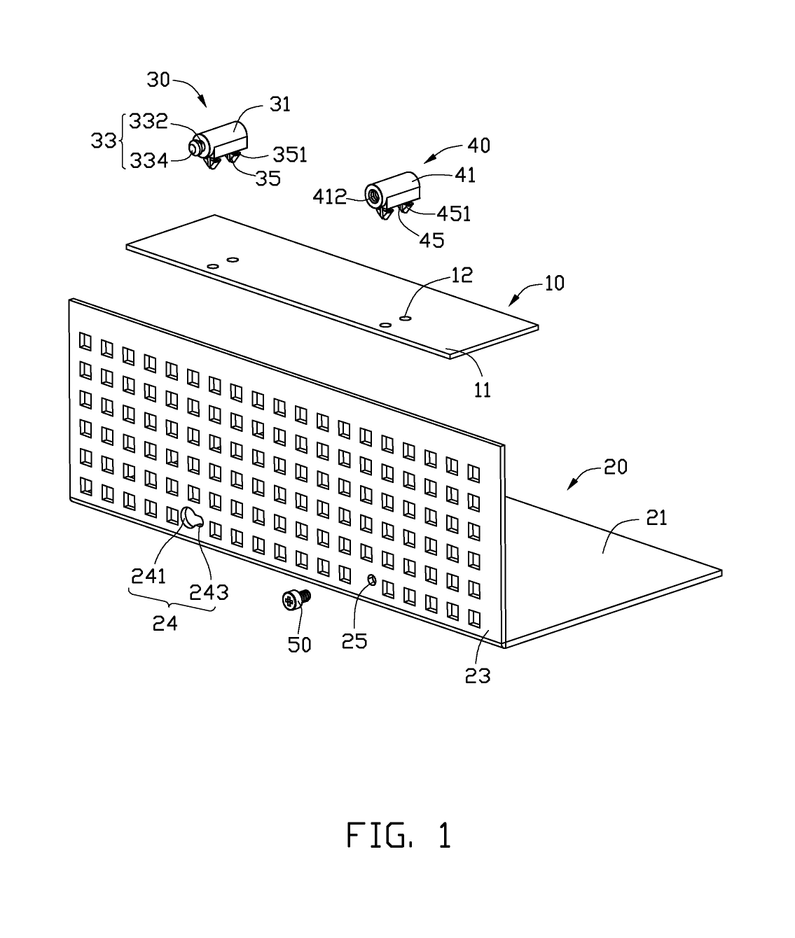

FIG. 1 shows a first embodiment of a circuit board mounting apparatus. The circuit board mounting apparatus includes a circuit board 10, a chassis 20, a first mounting member 30, a second mounting member 40, and a fastener 50. In the embodiment, the fastener is a screw 50.

Two pairs of latching holes 12 are defined in a front end 11 of the circuit board 10, through the top and the bottom of the circuit board 10.

The chassis 20 includes a bottom plate 21 and a side plate 23 extending up from the front side of the bottom plate 21 in a substantially perpendicular manner. A slide hole 24 and a through hole 25 are defined in the side plate 23, adjacent to the bottom plate 21. The slide hole 24 includes a first hole 241 away from the through hole 25, and a second hole 243 adjacent to the through hole 25, communicating with the first hole 241. A diameter of the first hole 241 is greater than a diameter of the second hole 243.

The first mounting member 30 includes a first main body 31, a latching portion 33 protruding from the front end of the first main body 31, and a pair of resilient first latching legs 35 extending down from the bottom of the first main body 31. The latching portion 33 includes a columnar neck 332 connected to the front end of the first main body 31, and a head 334 formed on the front end of the neck 332. A diameter of the head 334 is greater than a diameter of the neck 332. Each first latching leg 35 includes two opposite wedge-shaped hooks 351.

The second mounting member 40 includes a second main body 41, and a pair of resilient second latching legs 45 extending down from the bottom surface of the second main body 41. A horizontally extending fixing hole 412 is defined in the front end of the second main body 41. Each second latching leg 45 includes two opposite wedge-shaped hooks 451. In the embodiment, the fixing hole 412 is a threaded hole.

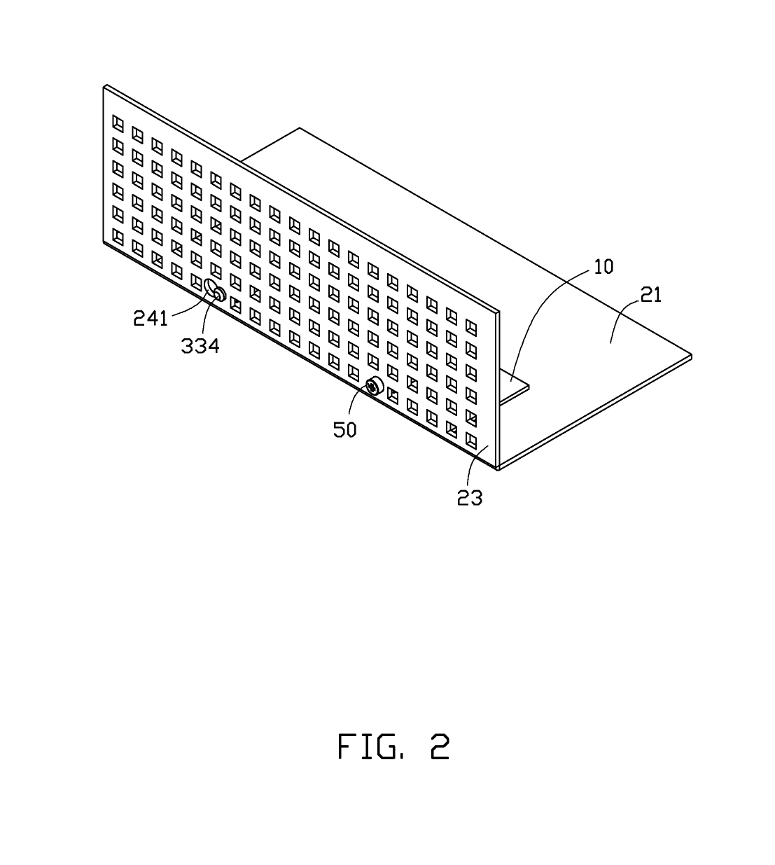

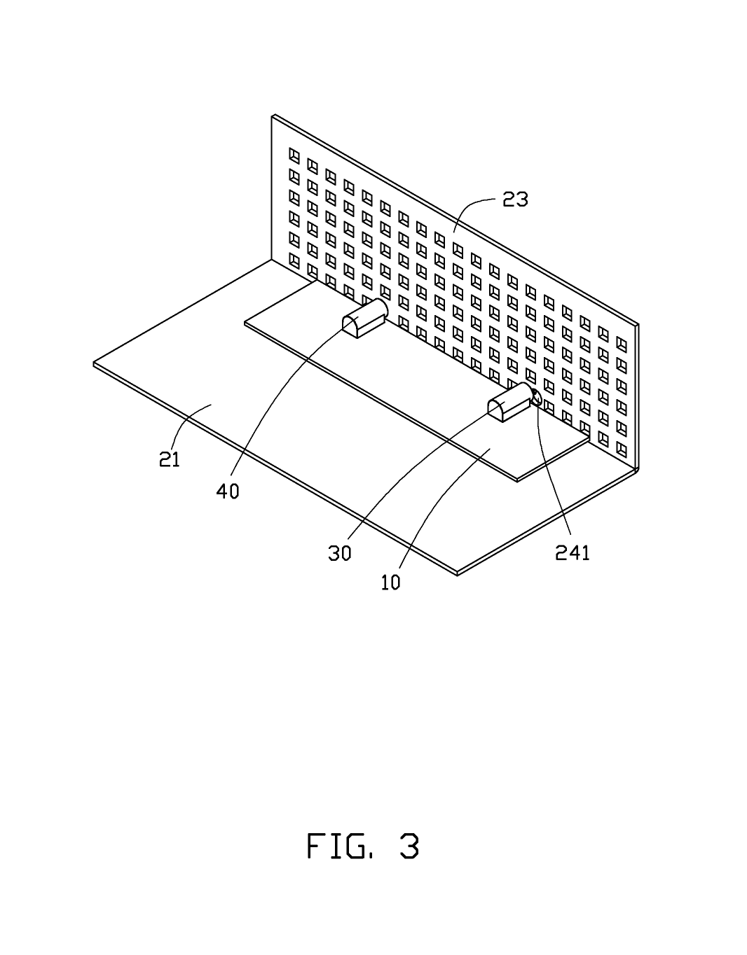

FIGS. 2 and 3 show that in assembly, the pairs of first and second latching legs 35 and 45 respectively extend through the pairs of latching holes 12, to allow the first and second main bodies 31 and 41 to be supported on the circuit board 10, and to allow the hooks 351 and 451 to engage with the bottom of the circuit board 10. Thereby, the first and second mounting members 30 and 40 are fixed to the front end 11 of the circuit board 10. The fixing hole 412 is parallel to the circuit board 10. The circuit board 10 is placed in the chassis 20, to allow the bottoms of the hooks 351 and 451 to be supported on the bottom plate 21. The head 334 is extended through the first hole 241, to allow the neck 332 to be received in the first hole 241. The front ends of the first and second main bodies 31 and 41 abut the rear side of the side plate 23. The circuit board 10 is slid horizontally along the side plate 23, to allow the neck 332 to engage in the second hole 243. The head 334 abuts the front side of the side plate 23. The fixing hole 412 aligns with the through hole 25. The fastener 50 extends through the through hole 25 and engages in the fixing hole 412. Thereby, the circuit board 10 is perpendicularly mounted to the side plate 23.

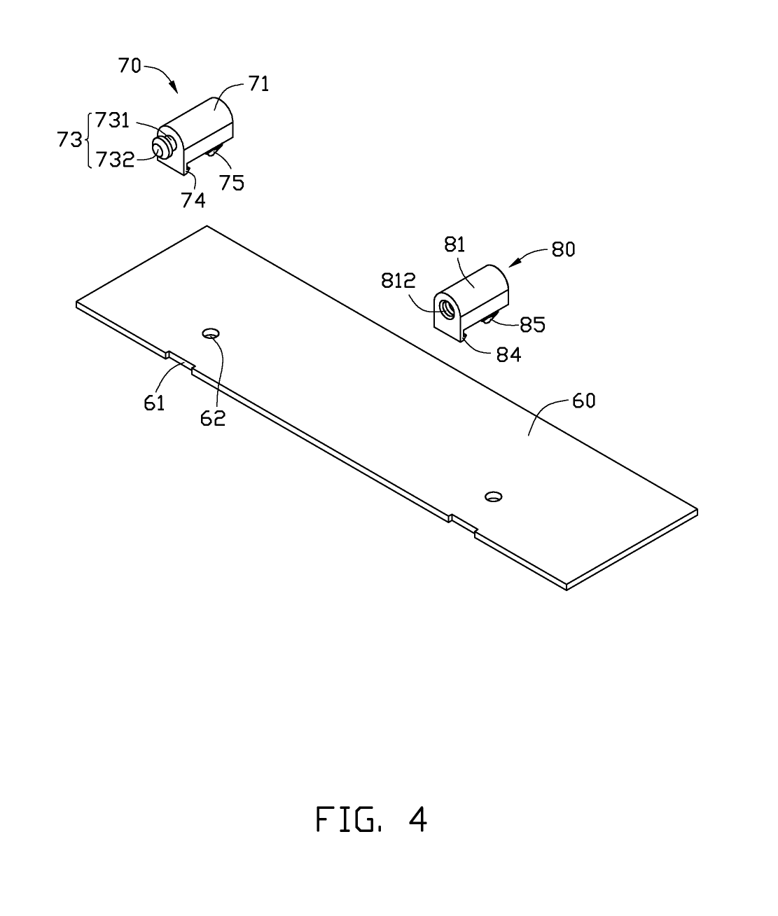

FIG. 4 shows a circuit board 60, a first mounting member 70, and a second mounting member 80 of a second embodiment of a circuit board mounting apparatus.

Two spaced slots 61 are defined in the front end of the circuit board 60, and two latching holes 62 are defined in the circuit board 60 respectively adjacent to the slots 61.

The first mounting member 70 includes a first main body 71, a latching portion 73 protruding from the front end of the first main body 71, and two first latching legs 74 and 75 extending down from the bottom of the first main body 71. The latching portion 73 includes a columnar neck 731 connected to the front end of the first main body 71, and a head 732 formed on the front end of the neck 731. A diameter of the head 732 is greater than a diameter of the neck 731. The first latching leg 74 is substantially L-shaped, and extends down and back from the front end of the bottom of the first main body 71. The first latching leg 75 includes two opposite wedge-shaped hooks extending downward from the rear end of the bottom of the first main body 71.

The second mounting member 80 includes a second main body 81, and two second latching legs 84 and 85 extending down from the bottom of the second main body 81. A horizontally extending fixing hole 812 is defined in the front end of the second main body 81. The second latching leg 84 is substantially L-shaped, and extends down and back from the front end of the bottom of the second main body 81. The second latching leg 85 includes two opposite wedge-shaped hooks extending downward from the rear end of the bottom of the second main body 81.

In assembly, the first and second latching legs 75 and 85 respectively extend through the latching holes 62, to allow the hooks to engage with the bottom of the circuit board 60, and to allow the bottoms of the first and second main bodies 70 and 80 to engage with the top of the circuit board 60. The first and second latching legs 74 and 84 respectively extend through the slots 612 and engage with the bottom of the circuit board 60. Thereby, the first and second mounting members 70 and 80 are fixed to the circuit board 60. Similar to the first embodiment, the circuit board 60 is placed in the chassis 20, to allow the bottoms of the hooks of the first and second latching legs 75 and 85 to be supported on the bottom plate 21. The head 732 is extended through the first hole 241, to allow the neck 731 to be received in the first hole 241. The front ends of the first and second main bodies 71 and 81 abut the rear side of the side plate 23. The circuit board 60 is slid horizontally along the side plate 23, to allow the neck 731 to engage in the second hole 243. The head 732 abuts the front side of the side plate 23. The fixing hole 812 aligns with the through hole 25. The fastener 50 extends through the through hole 25 and engages in the fixing hole 812. Thereby, the circuit board 60 is perpendicularly mounted to the side plate 23.

In each of the first and second embodiments, there is only one fastener to be installed when mounting a circuit board, and that are installed from outside of the chassis 20, which is convenient.

Even though numerous characteristics and advantages of the embodiments have been set forth in the foregoing description, together with details of the structure and the functions of the embodiments, the disclosure is illustrative only, and changes may be made in details, especially in the matters of shape, size, and arrangement of parts within the principles of the embodiments to the full extent indicated by the broad general meaning of the terms in which the appended claims are expressed.

What is claimed is:

1. A circuit board mounting apparatus, comprising:
a circuit board;
a chassis comprising a side plate defining a through hole, a first hole, and a second hole communicating with the first hole, wherein a diameter of the first hole is greater than a diameter of the second hole;
a first mounting member comprising a first main body, and two first latching legs extending down from a bottom of the first main body, to be detachably mounted to a front end of the circuit board, wherein a neck protrudes from a front end of the first main body, and a head is formed on a front end of the neck, the neck extends through the first hole and slides to engage in the second hole, the head abuts a front side of the side plate;
a second mounting member comprising a second main body, and two second latching legs extending down from a bottom of the second main body, to be detachably mounted to the front end of the circuit board, wherein a fixing hole parallel to the circuit board is defined in a front end of the second main body; and
a fastener extending through the through hole of the side plate and engaging in the fixing hole of the second mounting member, to perpendicularly mount the circuit board to the side plate.

2. The circuit board mounting apparatus of claim 1, wherein two latching holes are defined in the front end of the circuit board, each first latching leg of the first mounting member comprises two opposite hooks, to extend through a corresponding one of the latching holes and engage with a bottom of the circuit board.

3. The circuit board mounting apparatus of claim 1, wherein a slot is defined in the front end of the circuit board, and a latching hole is defined in the circuit board adjacent to the slot, one of the first latching legs is substantially L-shaped, and extends down and back from a front end of the bottom of the first main body, to extend through the slot and engage with a bottom of the circuit board, and the other first latching leg comprises two opposite hooks, to extend through the latching hole and engage with the bottom of the circuit board.

4. The circuit board mounting apparatus of claim 1, wherein two latching holes are defined in the front end of the circuit board, each second latching leg of the second mounting member comprises two opposite hooks, to extend through a corresponding one of the latching holes and engage with a bottom of the circuit board.

5. The circuit board mounting apparatus of claim 1, wherein a slot is defined in the front end of the circuit board, and a latching hole is defined in the circuit board adjacent to the slot, one of the second latching legs is substantially L-shaped, and extends down and back from a front end of the bottom of the first main body, to extend through the slot and engage with a bottom of the circuit board, and the other second latching leg comprises two opposite hooks, to extend through the latching hole and engage with the bottom of the circuit board.

6. The circuit board mounting apparatus of claim 1, wherein the second hole is arranged between the first hole and the through hole.

7. The circuit board mounting apparatus of claim 1, wherein a diameter of the head is greater than a diameter of the neck.

8. The circuit board mounting apparatus of claim 1, wherein the front ends of the first and second main bodies abut a rear side of the side plate.

9. The circuit board mounting apparatus of claim 1, wherein the fixing hole is a threaded hole, and the fastener is a screw.
